(19) United States
(12) Patent Application Publication
(10) Pub. No.: US 2022/0181537 A1
(43) Pub. Date: Jun. 9, 2022

(54) QUBIT READOUT

(71) Applicant: IQM Finland Oy, Espoo (FI)

(72) Inventors: Juha Hassel, Espoo (FI); Vasilii Sevriuk, Espoo (FI); Johannes Heinsoo, Espoo (FI); Kuan Yen Tan, Espoo (FI); Mikko Möttönen, Espoo (FI); Hao Hsu, Espoo (FI)

(21) Appl. No.: 17/406,243

(22) Filed: Aug. 19, 2021

(30) Foreign Application Priority Data
Dec. 8, 2020 (EP) 20212481.4

(51) Int. Cl. H01L 39/22; H01L 27/18; G06N 10/00

(52) U.S. Cl. CPC H01L 39/223; G06N 10/00; H01L 27/18

(57) ABSTRACT

It is an objective to provide an arrangement and a quantum computing system for qubit readout. According to an embodiment, an arrangement for qubit readout includes at least one qubit and a controllable energy relaxation structure comprising at least one junction. The controllable energy relaxation structure is coupled to the at least one qubit, and is configured to absorb, in response to a control signal, at least one photon from the at least one qubit via photon-assisted tunnelling of a charge through the at least one junction. The arrangement also includes a charge storage configured to store the tunnelled charge and a charge sensing structure coupled to the charge storage. The charge sensing structure is configured to provide a readout signal in response to detecting the tunnelled charge in the charge storage.

### PRIORITY CLAIM

This application claims priority to European Patent Application No. 20212481.4, filed on Dec. 8, 2020, the entire disclosure of which is incorporated by reference herein.

### TECHNICAL FIELD

The present disclosure relates to quantum computing, and more particularly to an arrangement and quantum computing system for qubit readout.

### BACKGROUND

In quantum computing, the basic operational unit is typically a two-level quantum system generally referred to as a qubit. After a quantum computation has been performed, for example, using a plurality of qubits, the state of one or more qubits needs to be read to obtain an intermediate or a final result of the computation. In addition to the readout, the qubit state initialization is often needed, preferably in an efficient manner, for subsequent quantum computations.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an objective to provide an arrangement for qubit readout in a quantum computing system. The foregoing and other objectives are achieved by the features of the independent claims. Further implementation forms are apparent from the dependent claims, the description, and the figures.

According to a first aspect, an arrangement for qubit readout comprises at least one qubit; a controllable energy relaxation structure comprising at least one junction, where the controllable energy relaxation structure is coupled to the at least one qubit, and is configured to absorb, in response to a control signal, at least one photon from the at least one qubit via photon-assisted tunnelling of a charge through the at least one junction; a charge storage configured to store the tunnelled charge; and a charge sensing structure coupled to the charge storage and configured to provide a readout signal in response to detecting the tunnelled charge in the charge storage. The arrangement is configured to, for example, provide a readout signal that indicates whether the at least one qubit was in a ground state or in an excited state. The arrangement may also reset the at least one qubit to a ground state.

In an implementation form of the first aspect, the at least one junction of the controllable energy relaxation structure comprises at least one normal metal-insulator-superconductor (NIS) junction, at least one superconductor-insulator-superconductor (SIS) junction, or at least one superconductor-insulator-quantum dot (SIQD) junction. The arrangement may be configured to, for example, relax the at least one qubit in an efficient manner using the at least one junction.

In a further implementation form of the first aspect, the charge sensing structure comprises a Coulomb blockade controlling the readout signal. The Coulomb blockade of the charge sensing structure may be modified by the charge stored in the charge storage coupled to the charge sensing structure. The arrangement may be configured to, for example, efficiently detect a charge in the charge storage.

In a further implementation form of the first aspect, the charge sensing structure comprises a single electron transistor (SET), a single Cooper pair transistor (SCPT), a radio-frequency single electron transistor (RF-SET), an inductive single electron transistor (L-SET), or a charge sensing structure based on semiconductor quantum dots, carbon nanotubes, quantum point contacts, or two-dimensional materials. The arrangement may be configured to, for example, efficiently detect a charge in the charge storage and provide the readout signal in response to the charge.

In a further implementation form of the first aspect, the at least one junction of the controllable energy relaxation structure comprises a superconductor-insulator-normal metal-insulator-superconductor (SINIS) junction, where the at least one qubit is electromagnetically coupled to the normal metal of the SINIS junction of the controllable energy relaxation structure. Additionally, the control signal corresponds to a voltage bias over the SINIS junction. The arrangement may be configured to, for example, relax the at least one qubit in an efficient and controllable manner using the at least one junction.

In a further implementation form of the first aspect, the charge storage is formed by at least a capacitive coupling between the at least one qubit and the controllable energy relaxation structure and a capacitance of the at least one junction of the controllable energy relaxation structure. The arrangement may be configured to, for example, efficiently store the charge in the charge storage for detection by the charge sensing structure.

In a further implementation form of the first aspect, the arrangement further comprises a charge leakage channel coupled to the charge storage that is configured to cause the tunnelled charge to decay in the charge storage. The arrangement may be configured to, for example, remove the tunnelled charge from the charge storage while being able to detect the charge before the decay.

In a further implementation form of the first aspect, at least one operating parameter of the at least one junction is configured in such a way that, when the control signal is applied, a photon-assisted tunnelling rate is greater than an elastic tunnelling rate in the at least one junction. The arrangement may be configured to, for example, read the state of the at least one qubit with improved reliability.

In a further implementation form of the first aspect, the at least one operating parameter comprises at least an operating temperature below 80 millikelvin and a Dynes parameter below 10⁻⁴.

In a further implementation form of the first aspect, the at least one qubit comprises at least one superconductive qubit.

According to a second aspect, a quantum computing system comprises the arrangement according to the first aspect and a control unit coupled to the arrangement. In this second aspect, the control unit is configured to provide the control signal to the controllable energy relaxation structure of the arrangement and detect the readout signal provided by the charge sensing structure of the arrangement. The system may be configured to, for example, read the state of the qubit in a controllable manner.

In an implementation form of the second aspect, the control signal comprises at least one unipolar or bipolar voltage pulse. The system may be configured to, for example, efficiently control the arrangement to provide the readout signal.

In a further implementation form of the second aspect, the at least one bipolar voltage pulse is temporally asymmetric. The system may be configured to, for example, enable the photon-assisted tunnelling using the first part of the pulse and empty the charge storage via elastic tunnelling using the second part of the pulse.

In a further implementation form of the second aspect, an amplitude of the at least one unipolar voltage pulse or of a first polarity part of the bipolar voltage pulse corresponds an energy less than a superconducting gap energy of the at least one junction of the controllable energy relaxation structure and greater than a difference of the superconducting gap energy of the at least one junction of the controllable energy relaxation structure and a qubit energy of the at least one qubit. The system may be configured to, for example, increase the probability that the charge in the charge storage corresponds to the state of the at least one qubit, which can improve accuracy of the readout signal.

According to a third aspect, a method for qubit readout in the arrangement according the first aspect comprises providing the control signal to the controllable energy relaxation structure of the arrangement and detecting the readout signal provided by the charge sensing structure of the arrangement. The method may enable, for example, reading the state of the qubit in a controllable manner.

According to a fourth aspect, a computer program product comprises program code configured to perform the method according to the third aspect when the computer program product is executed on a computer.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a schematic representation of an arrangement for qubit readout, according to an embodiment;

FIG. 2 illustrates a schematic representation of an arrangement for qubit readout comprising a SINIS junction, according to an embodiment;

FIG. 3 illustrates a schematic representation of an arrangement for qubit readout comprising a NIS junction, according to an embodiment;

FIG. 4 illustrates a schematic representation of an arrangement for qubit readout comprising a SIS junction, according to an embodiment;

FIG. 5 illustrates a schematic representation of an arrangement for qubit readout comprising a direct coupling between a charge storage and a SET, according to an embodiment;

FIG. 6 illustrates a schematic representation of an arrangement comprising a direct coupling between a charge storage and a SET for qubit readout, according to another embodiment;

FIG. 7 illustrates a schematic representation of a controllable energy relaxation structure comprising a SINIS junction, according to an embodiment;

FIG. 8 illustrates a plot representation of computed tunnelling rates in a QCR coupled to a resonator, according to an embodiment;

FIG. 9 illustrates a plot representation of computed transition rates in a SIQD junction, according to an embodiment;

FIG. 10 illustrates a schematic representation of a quantum computing system, according to an embodiment;

FIG. 11 illustrates a schematic representation of a control unit, according to an embodiment; and

FIG. 12 illustrates a flow chart representation of a method for qubit readout, according to an embodiment.

In the following, like reference numerals are used to designate like parts in the accompanying drawings.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined by the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

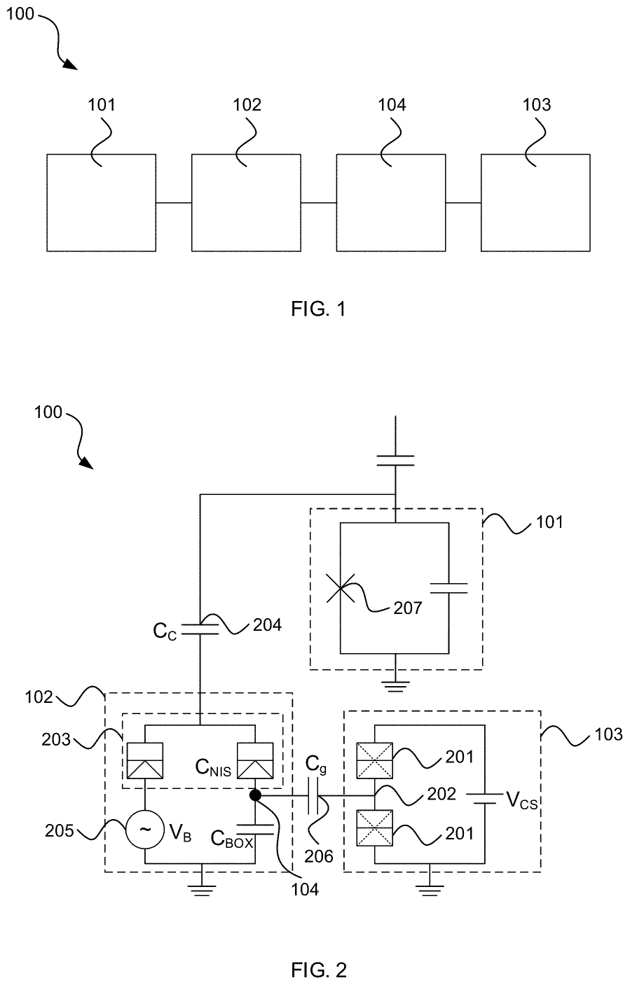

FIG. 1 illustrates a schematic representation of an arrangement 100 (e.g., an apparatus) for qubit readout, according to an embodiment.

According to an embodiment, the arrangement 100 comprises at least one qubit 101. The at least one qubit 101 may have a ground state |g [symbol] . Herein, the ground state may refer to a quantum state of the qubit having a lowest energy level.

The at least one qubit 101 may further have at least one excited state. The at least one excited state may comprise a lowest excited state |e [symbol] . Herein, the lowest excited state may refer to a quantum state of the qubit with a second lowest energy level.

The ground state and the lowest excited state of a qubit may correspond to the computational basis of the qubit. For example, the ground state |g [symbol] may correspond to the |0 [symbol] state of the qubit and the lowest excited state |e [symbol] may correspond to the |1 [symbol] state of the qubit or vice versa. Other quantum states of a qubit may be referred to as non-computational states.

The energy gap between the ground state and the lowest excited state may correspond to a resonance frequency of the qubit. The energy gap may also be referred to as the qubit energy, and the corresponding frequency as the qubit frequency.

The at least one excited state may further comprise a second lowest excited state |f [symbol] . The second lowest excited state has a higher energy than the ground state |g [symbol] and the lowest excited state |e [symbol] .

The arrangement 100 may further comprise a structure configured as a controllable energy relaxation channel, from here on referred to as a controllable energy relaxation structure 102. The example controllable energy relaxation structure 102 includes at least one junction and is coupled to the at least one qubit 101.

The controllable energy relaxation structure 102 may be configured to absorb, in response to a control signal, at least one photon from the at least one qubit 101 via photon-assisted tunnelling of a charge through the at least one junction. In this process, the energy of the photon corresponds to the qubit energy.

The controllable energy relaxation structure 102 may also be referred to as an environment, an engineered environment, a bath, a dissipation source, or similar.

The control signal may also be referred to as a control voltage, a bias voltage, a junction bias voltage, or similar. The control signal may correspond to a voltage over the at least one junction. The voltage over the at least one junction may be time-independent or time-dependent.

The controllable energy relaxation structure 102 may absorb the at least one photon from the at least one qubit 101 conditional to the at least one qubit 101 being in an excited state. If the at least one qubit 101 is in the ground state, the controllable energy relaxation structure 102 cannot absorb photon energy from the at least one qubit 101. Thus, the photon-assisted tunnelling cannot occur, and tunnelling through the junction is not favourable since a charge does not have sufficient energy to tunnel through the at least one junction. In some embodiments, the controllable energy relaxation structure 102 is designed and tuned in such manner that the photon-assisted tunnelling, as a control signal is applied, is very likely conditional to the qubit being in an excited state, whereas all other possible tunnelling mechanisms are very unlikely. Therefore, an event of tunnelling is a high probability indication of the qubit being in an excited state.

The arrangement 100 may further comprise a charge storage 104. The charge storage 104 may be configured to store the tunnelled charge.

The charge storage 104 may also be referred to as a single-charge storage, a charge box, a single-charge box, or similar.

The tunnelled charge may correspond to, for example, an electron, a Cooper pair, an electron hole, or a quasi-particle, depending on the type of the at least one junction.

The charge storage 104 may be embodied in the controllable energy relaxation structure 102. Alternatively, the charge storage 104 may be a separate element from the controllable energy relaxation structure 102.

The arrangement 100 may further comprise a charge sensing structure 103 coupled to the charge storage 104. The charge sensing structure 103 may be configured to provide a readout signal in response to detecting the tunnelled charge in the charge storage 104.

The readout signal may also be referred to as a readout voltage, a readout current, a qubit readout signal, or similar.

Since the photon-assisted tunnelling is conditional to the at least one qubit 101 being in an excited state, the readout signal can indicate the state of the at least one qubit 101. Further, the photon-assisted tunnelling can reset the at least one qubit 101 into the ground state. Thus, the arrangement 100 may provide a qubit readout and/or a qubit reset capability. Further, the arrangement 100 may be integrated in a compact manner within a quantum circuit.

Herein, when two elements are electromagnetically coupled, the elements may have an electromagnetic connection between each other. The electromagnetic connection may comprise any number of electrical components/elements, such as capacitors, inductors, mutual inductances, transmission lines etc.

Although some embodiments and analysis disclosed herein may refer to specific implementations of the controllable energy relaxation structure 102, it should be appreciated that the controllable energy relaxation structure 102 may be implemented using, for example, any controllable energy relaxation structure with a coupling to the at least one qubit 101.

The controllable energy relaxation structure 102 may be electromagnetically coupled to the at least one qubit 101. The controllable energy relaxation structure 102 may be controllable in the sense that its tendency to provide photon-assisted tunnelling, conditional to the at least one qubit 101 being in an excited state, depends on the control signal.

It should be appreciated that although the at least one qubit 101 and the controllable energy relaxation structure 102 may be electromagnetically coupled continuously, the relaxation rate of the qubit 101 as inflicted by the controllable energy relaxation structure 102 may still be selective, if the properties of the relaxation structure 102 can be controlled. The effect of the control signal can, for example, be such that when the control signal is applied, the photon-assisted tunnelling becomes energetically favourable with photon energies corresponding to the difference of the energies of the excited and ground states of the qubit 101. In some embodiments, when the control signal is not applied, the photon assisted tunnelling is highly unlikely irrespective of the qubit 101 state.

Herein, when the properties of the controllable energy relaxation structure 102 are controllable, the strength of interaction between the controllable energy relaxation structure 102 and other objects may be controlled and/or turned on or off. It should be appreciated that even if there is a continuous connection, such as an electrical/capacitive/inductive connection, between two elements, the interaction between the elements can be tuned.

According to an embodiment, the at least one qubit 101 comprises at least one superconductive qubit.

According to an embodiment, the at least one qubit 101 comprises at least one Josephson junction.

According to an embodiment, the at least one qubit 101 comprises a transmon qubit. Alternatively, the at least one qubit 101 may comprise any other type of qubit, such as, a flux qubit, a charge qubit, a phase qubit, or a fluxonium qubit.

Although some embodiments may be disclosed herein with reference to a certain type of qubit, these qubit types are only exemplarily. In any embodiment disclosed herein, the at least one qubit 101 may be implemented in various ways and using various technologies.

The arrangement 100 may be embodied in, for example, a quantum computing device. Such a quantum computing device may comprise a plurality of qubits for performing quantum computations. Each such qubit may be implemented using the arrangement 100.

The arrangement 100 may be realized, for example, in a superconducting circuit architecture.

When the arrangement 100 is operational, the at least one qubit 101, the controllable energy relaxation structure 102, the charge storage 104, and/or the charge sensing structure 103 may be physically located in a cryostat or similar. The cryostat may cool the at least one qubit 101 and other components of the arrangement 100, such as the controllable energy relaxation structure 102, to cryogenic temperatures. This may be required if the at least one qubit 101 correspond to, for example, a superconductive qubit.

FIG. 2 illustrates a schematic representation of an arrangement 100 comprising a SINIS junction, according to an embodiment.

It should be appreciated that only some elements and/or couplings between elements are illustrated in the embodiments disclosed herein. When the arrangement 100 is used in, for example, quantum computing applications, the at least one qubit 101 may be coupled to other qubits and elements used to control the at least one qubit 101.

According to an embodiment, the at least one junction of the controllable energy relaxation structure 102 comprises a superconductor-insulator-normal metal-insulator-superconductor (SINIS) junction. The at least one qubit 101 may be electromagnetically coupled to the normal metal of the SINIS junction of the controllable energy relaxation structure 102. The control signal may correspond to a bias voltage 205 over the SINIS junction.

In the embodiment of FIG. 2, the at least one qubit 101 is a transmon qubit comprising a Josephson junction 207 and the at least one junction in the controllable energy relaxation structure 102 comprises a SINIS junction 203. A SINIS junction may comprise two NIS junctions. A controllable energy relaxation structure 102 comprising a SINIS junction 203 may also be referred to as a quantum circuit refrigerator (QCR). The at least one qubit 101 is coupled to the QCR via a coupling capacitance C_{C} 204.

In the embodiment of FIG. 2, the control signal may correspond to the bias voltage V_{B} over the SINIS junction. The bias voltage V_{B} provides a signal controlling the likelihood of photon-assisted tunnelling (conditional to the qubit 101 being in an excited state). In this sense, the arrangement 100 is capable of performing a reset of the qubit 101. However, the arrangement 100 is also capable of storing the electron in the charge storage 104 after the photon-assisted tunnelling event. The stored electron can then be sensed by the charge sensing structure 103.

According to an embodiment, the charge storage 104 is formed by at least a capacitive coupling between the at least one qubit 101 and the controllable energy relaxation structure 102 and a capacitance of the at least one junction of the controllable energy relaxation structure 102.

According to an embodiment, the charge storage 104 is formed by at least a capacitive coupling between the at least one qubit 101 and the controllable energy relaxation structure 102, a capacitance of the at least one junction of the controllable energy relaxation structure 102, and a capacitive coupling between the charge sensing structure 103 and the controllable energy relaxation structure 102.

For example, in the embodiment of FIG. 2, the charge storage 104 comprises a single-charge box formed by the capacitance of the QCR, a capacitance C_{NIS}, a capacitance C_{BOX}, and the gate-capacitor C_{g} 206 of the charge sensing structure 103.

According to an embodiment, the charge sensing structure 103 comprises a structure where electron transport at the output is affected by a Coulomb blockade. In an embodiment, the charge sensing structure 103 is coupled to the charge storage 104 in such a way that the stored charge modifies the Coulomb blockade of the charge sensing structure 103.

According to an embodiment, the charge sensing structure 103 comprises a Coulomb blockade controlling the readout signal. The Coulomb blockade of the charge sensing structure may be modified by the charge stored in the charge storage 104 coupled to the charge sensing structure 103.

According to an embodiment, the charge sensing structure 103 comprises a single electron transistor (SET), a single Cooper pair transistor (SCPT), a radio-frequency single electron transistor (RF-SET), an inductive single electron transistor (L-SET), or a charge sensing structure based on semiconductor quantum dots, carbon nanotubes, quantum point contacts, or two-dimensional materials.

According to an embodiment, the charge sensing structure 103 comprises a single-electron transistor (SET) or a single Cooper pair transistor (SCPT) comprising a conductive island 202. The conductive island 202 of the SET or SCPT may be coupled to the charge storage 104. The readout signal may correspond to an electrical current through the SET or SCPT. The conductive island 202 may be, for example, capacitively coupled to the charge storage 104. The SET may be voltage biased.

A SET or SCPT may comprise two normal conducting or superconducting tunnel junctions 201 and a conductive island 202 between the tunnel junctions 201. The electrical potential of the island 202 can be tuned with at least one gate electrode to optimize the operating point for the charge sensing structure 103. Applying a voltage at the gate electrode (not shown in the figures for clarity), the island 202 can be tuned close to a threshold where the presence of a charge in the charge storage 104 has a large impact on the charge transport at the output of the charge sensing structure. For example, when the tunnelled charge is in the charge storage 104 and the SET is biased by a voltage V_{CS}, a current can flow through tunnel junctions 201 and the SET. This current can function as the readout signal.

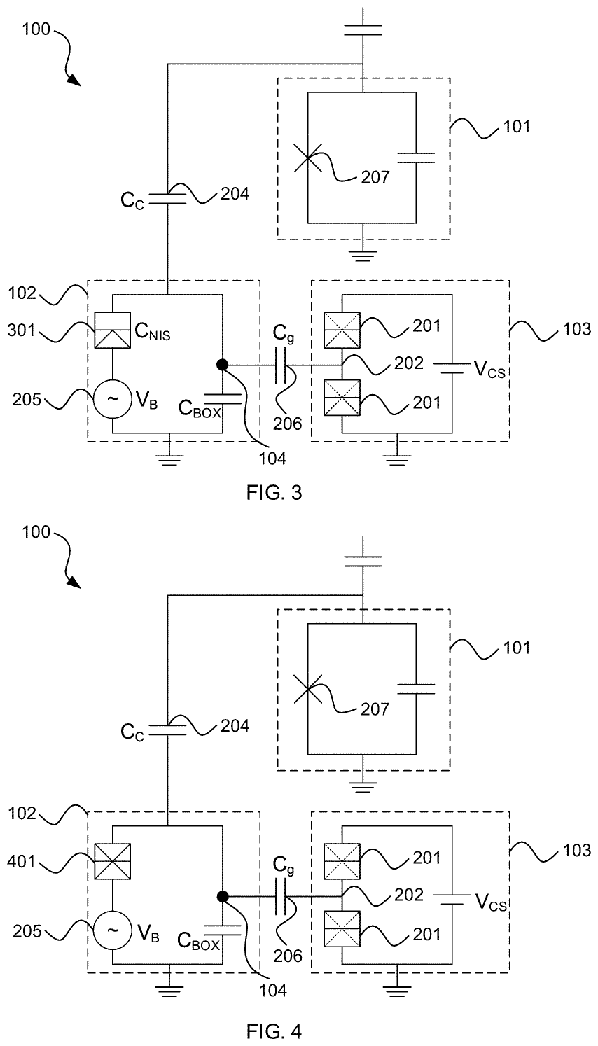

FIG. 3 illustrates a schematic representation of an arrangement 100 comprising a NIS junction, according to an embodiment.

According to an embodiment, the at least one junction of the controllable energy relaxation structure 102 comprises at least one normal metal-insulator-superconductor (NIS) junction, at least one superconductor-insulator-superconductor (SIS) junction, or at least one a superconductor-insulator-quantum dot (SIQD) junction.

In the embodiment of FIG. 3, at least one junction of the controllable energy relaxation structure 102 comprises a NIS junction 301.

Photon-assisted tunnelling involves a tunnelling process where the qubit excitation energy enables a tunnelling process which otherwise is not favorable due to an energy barrier of the at least one junction. In case of solutions based on NIS junctions, such as in the embodiments of FIG. 2 and FIG. 3, the barrier is the superconducting energy gap, possibly accompanied by a Coulomb gap depending on the charging energies.

FIG. 4 illustrates a schematic representation of an arrangement 100 comprising a SIS junction, according to an embodiment. In the embodiment of FIG. 4, the at least one junction of the controllable energy relaxation structure 102 comprises a SIS junction 401.

In superconducting implementations of the controllable energy relaxation structure 102, such as the embodiment of FIG. 4, the tunnelling can be based on single Cooper pair tunnelling, and the energy gap is the Coulomb gap related to the charging energy. Alternatively, also in all-superconducting versions, the tunnelling can be based on quasiparticle tunnelling, in which a case energy gap can be again a combination of the superconducting gap and the Coulomb gap. All-superconducting version could be beneficial as the fabrication technique can be readily compatible with the qubit process with no extra layers.

In some embodiments, the at least one junction of the controllable energy relaxation structure 102 may comprise a SIQD junction. For example, in the embodiment of FIG. 3, the NIS junction may be replaced with a SIQD junction or in the embodiment of FIG. 4, the SIS junction can be replaced with a SIQD junction. In the case of the NIS junction of the embodiment of FIG. 3, for example, with high Coulomb energy, the arrangement 100 can use the charge sensing structure 103 to detect charge transfer. However, if the charge storage 104 has both a high Coulomb energy and high energy level separation in the electron density of states, such as with a quantum dot, such a structure can also be utilized.

Further, in some embodiments, the controllable energy relaxation structure 102 may further comprise a mirrored SIQD junction in place of the C_{box} capacitance. “Mirrored” indicates that the quantum dot side of the mirrored SIQD junction is coupled to the charge storage 104 while the superconductor side of the mirrored SIQD junction is coupled to the ground. The transition rates are different in such embodiments.

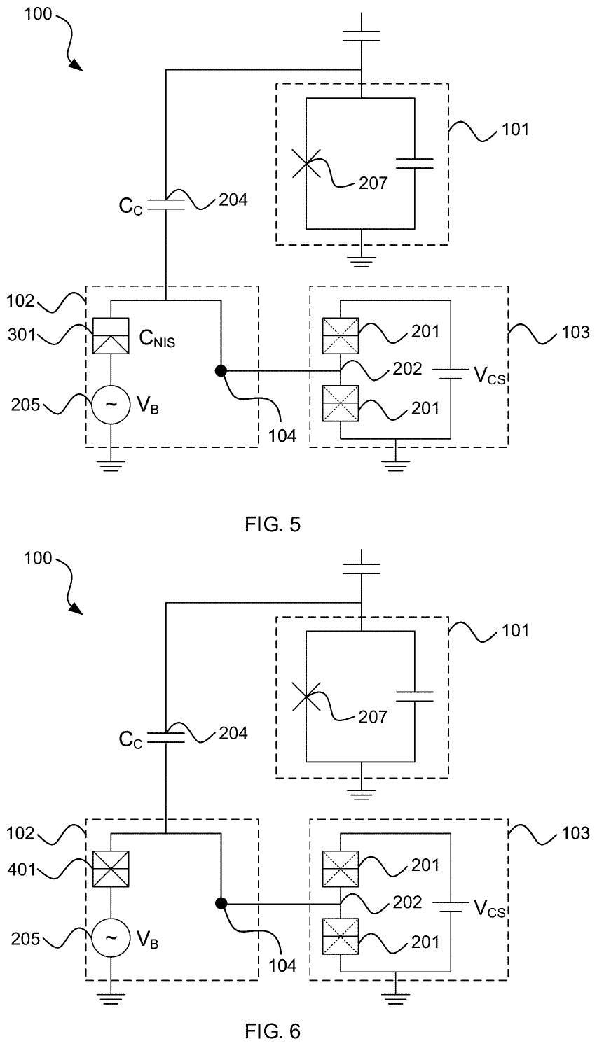

FIG. 5 illustrates a schematic representation of an arrangement 100 comprising a direct coupling between a charge storage 104 and a SET, according to an embodiment. In the embodiment of FIG. 5, the at least one junction of the controllable energy relaxation structure 102 comprises a NIS junction 301 and the charge storage 104 is directly electrically coupled to the conductive island 202 of the SET.

FIG. 6 illustrates a schematic representation of an arrangement 100 comprising a direct coupling between a charge storage 104 and a SET, according to an embodiment. In the embodiment of FIG. 6, the at least one junction of the controllable energy relaxation structure 102 comprises a SIS junction 401 and the charge storage 104 is directly electrically coupled to the conductive island 202 of the SET.

In the embodiments of FIGS. 2-4, the charge-sensing device 103 is capacitively coupled to the charge storage 104. In directly coupled embodiments, such as the embodiment of FIG. 5 or the embodiment of FIG. 6, the charge (Cooper pair or quasiparticle) can tunnel directly to the conductive island 202 of the SET by the photon-assisted tunnelling process in the at least one junction. In these embodiments, the charge signal as seen by the charge sensing structure 103 may be increased. Yet, these embodiments may have restrictions as the charge decay through the charge sensing structure 103 may set constraints to the design.

Although the SET has been used as an example of the charge sensing structure 103 in the embodiments of FIGS. 2-6, the charge sensing structure 103 may be implemented in various other ways. The common feature of a charge sensing structure is that the charge sensing structure has sufficient resolution to sense the tunnelled charge in the charge storage 104.

In certain embodiments, the charge sensing structure 103 is any structure in which the charge in the charge storage 104 affects the strength of the Coulomb blockade in the charge sensing structure 103, and in which the electrical transport at the output of the charge sensing structure 103 is dependent on the strength of the Coulomb blockade. The electrical transport may refer to current or voltage at the output of the charge sensing structure 103. In some embodiments, the changes in the electrical transport properties are sensed by probing with a radio-frequency signal.

In any embodiment disclosed herein, the charge sensing structure 103 may comprise, for example, a single-electron transistor (SET) producing a charge-dependent current. The SET may be, for example, a superconducting SET, also referred to a single Cooper pair transistor (SCPT), a normal SET, or an inductive SET (L-SET). The SET may be read out with radio-frequency signals. Options also include devices based on quantum point contacts (QPCs), carbon nanotubes (CNTs), 2D materials such as graphene, or semiconductor-based single electron devices such as semiconductor quantum dots. In some embodiments, there is a further tuning option through gate-based tuning of the tunnel coupling.

It may be advantageous to integrate the charge sensing structure 103 to a separate chip using, for example, flip-chip bonding. The flip-chip bonding can further enable hybridizing different technologies such as those related to the fabrication of the charge sensing structure 103. As an example, one can anticipate an option to hybridize a semiconductor quantum-dot-based charge sensing structure 103 with a superconducting qubit.

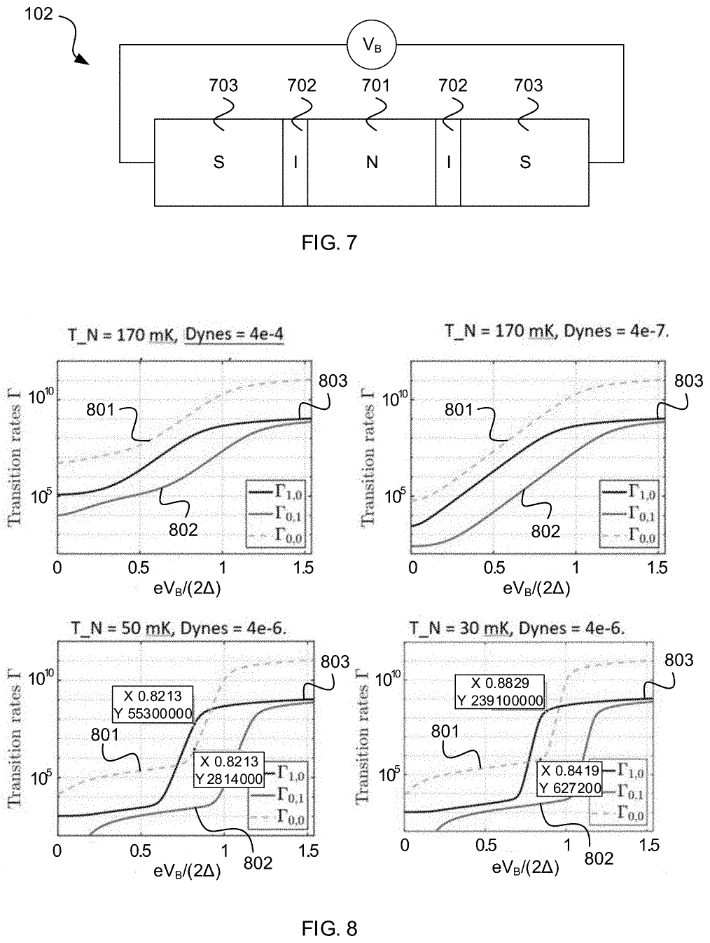

FIG. 7 illustrates a schematic representation of a controllable energy relaxation structure 102 comprising a SINIS junction, according to an embodiment. The at least one junction of the controllable energy relaxation structure 102 may be implemented, for example, as in the embodiment of FIG. 7.

In the embodiment of FIG. 7, the controllable energy relaxation structure 102 comprises two NIS junctions. These two NIS junctions form a superconductor 703-insulator 702-normal metal 701-insulator 702-superconductor 703 (SINIS) junction. The SINIS junction may be biased by a bias voltage V_{B}.

The energy relaxation properties of the SINIS junction can be controlled by the bias voltage V_{B}. The SINIS junction may be referred to as a quantum circuit refrigerator (QCR). In some embodiments, the bias voltage V_{B} is time-dependent.

The at least one qubit 101 may be electromagnetically coupled to the SINIS junction of the controllable energy relaxation structure 102. Thus, the energy relaxation structure 102 may absorb photon energy from the at least one qubit 101.

The controllable energy relaxation structure 102 may absorb photons from the at least one qubit 101 at bias voltages where an electron needs to receive an additional energy quantum from the at least one qubit 101 to overcome the Bardeen-Cooper-Schrieffer (BCS) energy gap in the superconductor 703. For example, if eV_{B}<2Δ, there is ideally only a small probability of electron tunnelling through the SINIS junction spontaneously. Moreover, if eV_{B}+hf>2Δ, an electron can tunnel via photon-assisted tunnelling with the absorption of a photon of energy hf. Here Δ is the BCS gap or superconducting gap of the superconducting electrode material, V_{B} is the bias voltage, e is the electron charge, h is the Planck constant, and f is the frequency of the photon. If, furthermore, the energy hf corresponds to the energy difference of the excited and ground states of the qubit, the qubit is in its excited state, and if the SINIS junction is electromagnetically coupled to the qubit, the qubit can relax from the excited state to the ground state through the relaxation channel provided by the photon-assisted tunnelling in the SINIS junction. However, if eV_{B}+hf<2Δ, the photon-assisted tunnelling is ideally forbidden. Thus, a time-dependent control signal V_{B} can be used to trigger a readout process of the qubit.

FIG. 8 illustrates a plot representation of computed tunnelling rates in a QCR coupled to a resonator, according to an embodiment. In addition to the above-discussed ideal situation, the rates are computed from a model including a finite temperature T_{N} and a junction quality quantified by the so-called Dynes parameter.

The model used for the embodiment of FIG. 8 does not include the charging effects related to the charge storage 104 and the charge sensing structure 103 coupled to the charge storage 104. This is anticipated to be addressable by modifying the bias conditions. Indeed, the presence of the charge storage 104 and the charge sensing structure 103, as well as the Coulomb blockade related to it, may impact the considered voltage scales in an order of e/C_{Σ} (with e being the electron charge and C_{Σ} being the total capacitance related to the charge storage 104, including contributions from the capacitances of the controllable energy relaxation structure 102 and charge sensing device 103). If Δ is much greater than e/C_{Σ} the correction can be neglected. The model also assumes a linear resonator rather than a qubit, but the cases may be considered as essentially equivalent if one only considers the lowest two states of the qubit. Thus, the model can be considered sufficient for illustrating the operating principle of at least some embodiments of the arrangement 100.

In the embodiment of FIG. 8, Γ_{i,j} denotes the transition rate of the resonator (qubit) from state |i [symbol] to state |j [symbol] . Thus, Γ_{1,0}, represented by curve 803, corresponds to the photon-assisted tunnelling process, where a photon is emitted from the qubit and the qubit transitions from the lowest excited state to the ground state. Γ_{0,1}, represented by curve 802, corresponds to a process in which the qubit absorbs a photon and transitions from the ground state to the lowest excited state. Γ_{0,0}, represented by curve 801, corresponds to a process in which the qubit remains in the ground state but tunnelling still occurs in the at least one junction. This may be referred to as elastic tunnelling.

The desired photon-assisted tunnelling event is depicted in the embodiment FIG. 8 by curve 803, which shows the photon-assisted tunnelling rate conditional to the at least one qubit 101 being in an excited state. The interpretation is that as controllable energy relaxation structure 102 is in the off-state (V_{B}/2Δ≈0, with V_{B} being the bias voltage of the QCR and Δ being the superconducting gap of the material), i.e. no control signal is applied, the tunnelling probability is low. As V_{B}/2Δ is increased close to unity, the rate increases by several orders of magnitude. Thus, the most basic case is to realize the control signal as a unipolar voltage pulse with an amplitude V_{B}/2Δ close to but less than unity, and duration Δt such that the odds are that the qubit decays to the ground state with a high probability during the process.

One challenge is to prevent the effect of any unwanted tunnelling events. From the embodiment of FIG. 8, it appears that the so-called elastic tunnelling independent of the qubit state, represented by curve 801, often exceeds the photon-assisted tunnelling, thus potentially causing a “false positive” of a qubit being in an excited state to the readout signal. Therefore, the parameter regime of interest may be where, during the reset/readout pulse, the photon-assisted tunnelling Γ_{1,0} substantially exceeds the elastic tunnelling Γ_{0,0}.

Beneficial operating points can be found if the operating temperature T_{N} is low enough, and if the Dynes parameter describing the deviation of superconductor density of states from ideal (or spurious environment-induced photon-assisted tunnelling) is low enough. Potential high-fidelity operating points in this respect are labelled in the bottom plots of FIG. 8. Examples of such points are when T_{N}=50 millikelvin (mK), the Dynes parameter is 4×10⁻⁶, and eV_{B}/2Δ≈0.8213 or when T_{N}=30 mK, Dynes parameter is 4×10⁻⁶, and eV_{B}/2Δ≈0.8829. It can be also noted the criterion Γ_{1,0}>>Γ_{0,0} at the operating point essentially follows from the readout requirement, whereas this criterion may not be necessary for a pure reset process of the at least one qubit 101. One can further note that the advantageous operating temperatures are available in common qubit environments, and Dynes parameters down to 0.5×10⁻⁶ are reported in the literature.

According to an embodiment, at least one operating parameter of the at least one junction is configured in such a way that, when the control signal is applied, a photon-assisted tunnelling rate is greater than an elastic tunnelling rate in the at least one junction.

According to an embodiment, the at least one operating parameter comprises at least an operating temperature below 80 millikelvin and a Dynes parameter below 10⁻⁴.

The readout error can be minimized by optimizing the readout pulse duration. In a simplified model, the readout error events are considered of a) failed photon assisted tunnelling when the qubit is in the excited state, and b) a tunnelling event even when the qubit is in the ground state. Assuming for simplicity a rectangular reset/readout pulse of duration Δt, the fidelity (i.e. the probability of correct measurement result) corresponding to a) is, from the properties of exponentially distributed random events, P₁=1−exp(−Γ_{1,0}Δt), i.e. the probability of photon assisted tunnelling conditional to the qubit being in the excited state. The fidelity corresponding to b) is P₂=exp(−Γ_{0,0}Δt), i.e. the probability of photon not tunnelling by the inelastic process independently of the qubit state. The maximum overall fidelity can be defined as the worst case, i.e., min(P₁,P₂). As P₁ increases and P₂ decreases with increasing Δt the optimum is at P₁=P₂. For the case of the Dynes parameter of 0.5×10−6 and temperature T_{N} of 10 mK and using a model similar to that applied in FIG. 8 for rates Γ_{0,0} and Γ_{1,0} the maximum fidelity of about 99.8% corresponding to the readout pulse length of about 21 ns.

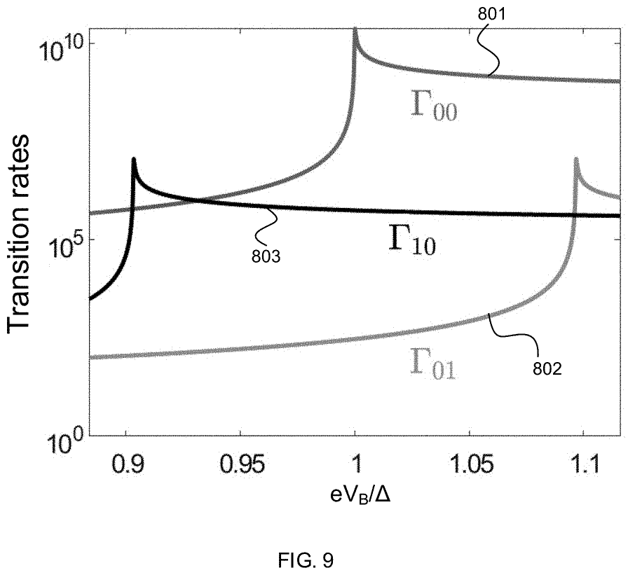

FIG. 9 illustrates a plot representation of computed transition rates in SIQD junction, according to an embodiment.

SIQD junction can be operated at the peak of the Γ_{1,0} rate. At this peak, Γ_{1,0} can be approximately 20 times greater than Γ_{0,0}. However, a lower Dynes parameter of 5×10⁻⁷, which also corresponds to one of the cases disclosed in the embodiment of FIG. 8, leads to the much higher ratio of 60×10³ and thus the fidelity of this scheme is approximately 99.985% corresponding to the readout pulse length of about 48 ns. Furthermore, the temperature of the normal metal does not affect the results, and thus the effects related to the quasiparticles heating will not affect the operation, since level separation in the quantum dot is much greater than a typical value for kT.

The quantum dot level separation energy and the Coulomb energy of the quantum dot should be greater than the superconducting gap. Such a quantum dot can be manufactured out of, for example, carbon nanostructures and other semiconducting materials.

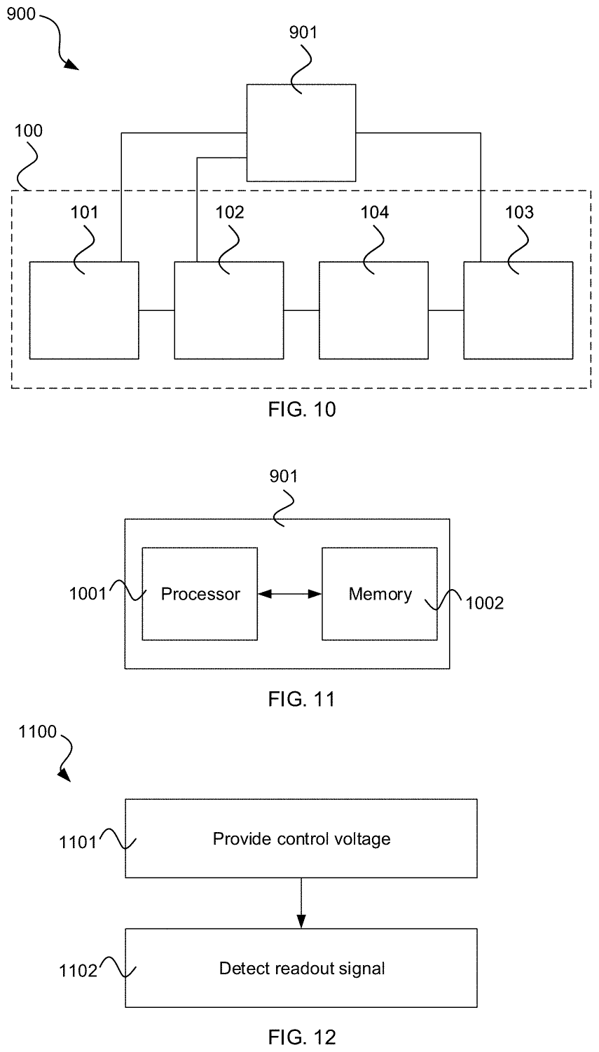

FIG. 10 illustrates a schematic representation of a quantum computing system 900, according to an embodiment.

According to an embodiment, the quantum computing system 900 comprises the arrangement 100 and a control unit 901 coupled to the arrangement 100. The control unit 901 may be configured to provide the control signal to the controllable energy relaxation structure 102 of the arrangement 100. The control unit 901 may be further configured to detect the readout signal provided by the charge sensing structure 103 of the arrangement 100.

In some embodiments, the quantum computing system 900 may comprise a plurality of qubits. The readout of each qubit in the plurality of qubits may be implemented using the arrangement 100. The control unit 901 may be coupled to each such arrangement 100 and the control unit 901 may control each arrangement 100 in a manner disclosed herein. Further, the control unit 901 may perform quantum computation using the plurality of qubits.

The control unit 901 may be configured to directly measure the readout signal provided by the charge sensing structure 103. Alternatively, there may be other stages, such as one or more amplifiers, between the control unit 901 and the charge sensing structure 103. The need for such other stages may depend on the strength of the signal provided by the charge sensing structure 103 and/or the sensitivity of the control unit 901. Further, there may be other elements between the charge sensing structure 103 and the control unit 901, such as an analogue-to-digital converter, that may adapt the readout signal to a format suitable for the control unit 901.

After the control unit 901 has detected the readout signal, the tunnelled charge should be removed from the charge storage 104 to, in turn, initialize the charge readout structure 103. One solution is to apply pulse shaping to the control signal in such a way that the control signal has a shape, e.g. a bipolar pulse shape (likely asymmetric bipolar pulse shape), such that after the actual trigger enabling the photon-assisted tunnelling, there is a pulse emptying the charge storage 104 through elastic tunnelling. Also, more complex pulse shapes can be applied.

According to an embodiment, the control signal comprises at least one unipolar or bipolar voltage pulse.

The bipolar voltage pulse may comprise a first polarity part and a second polarity part. The first polarity part and the second polarity part may have opposing polarities. For example, the first polarity part may correspond to a positive voltage and the second polarity part may correspond to a negative voltage or vice versa. The first polarity parts and the second polarity part may be temporally consecutive.

An amplitude of the at least one unipolar voltage pulse or an amplitude of a first polarity part of the bipolar voltage pulse may be configured to enable the photon-assisted tunnelling in the at least one junction.

According to an embodiment, an amplitude of the at least one unipolar voltage pulse or of a first polarity part of the bipolar voltage pulse corresponds an energy less than a superconducting gap energy of the at least one junction of the controllable energy relaxation structure 102 and greater than a difference of the superconducting gap energy of the at least one junction of the controllable energy relaxation structure 102 and a qubit energy of the at least one qubit 101.

An amplitude of a second polarity part of the bipolar voltage pulse may be configured to enable elastic tunnelling of the tunnelled charge in the at least one junction.

The control unit 901 may be configured to detect the readout signal after providing the first polarity part of the bipolar voltage pulse and before applying the second polarity part of the bipolar voltage pulse.

According to an embodiment, the at least one bipolar voltage pulse is temporally asymmetric.

Alternatively or additionally, the tunnelled charge may be removed from the charge storage by using a charge leakage channel.

According to an embodiment, the arrangement 100 further comprises a charge leakage channel coupled to the charge storage 104. The charge leakage channel may be configured to cause the tunnelled charge to decay in the charge storage 104.

The leakage channel may, for example, replace C_{BOX}. The leakage channel may comprise, for example, a tunnel junction or a resistor through which the tunnelled charge can decay spontaneously. The decay rate may be low enough for the charge sensing structure 103 to detect the tunnelled charge.

FIG. 11 illustrates a schematic representation of a control unit 901, according to an embodiment.

The control unit 901 may comprise at least one processor 1001. The at least one processor 1001 may comprise, for example, one or more of various processing devices, such as a co-processor, a microprocessor, a logic implementer, a digital signal processor (DSP), a processing circuitry with or without an accompanying DSP, or various other processing devices including integrated circuits such as, for example, an application specific integrated circuit (ASIC), a field programmable gate array (FPGA), a microprocessor unit (MCU), a hardware accelerator, a special-purpose computer chip, or the like.

The control unit 901 may further comprise a memory 1002. The memory 1002 may be configured to store, for example, computer programs, machine-readable instructions, and the like. The memory 1002 may comprise one or more volatile memory devices, one or more non-volatile memory devices, and/or a combination of one or more volatile memory devices and non-volatile memory devices. For example, the memory 1002 may be embodied as magnetic storage devices (such as hard disk drives, floppy disks, magnetic tapes, etc.), optical magnetic storage devices, and semiconductor memories (such as mask ROM, PROM (programmable ROM), EPROM (erasable PROM), flash ROM, RAM (random access memory), etc.).

The control unit 901 may further comprise other components not illustrated in the embodiment of FIG. 12. The control unit 901 may include, for example, an input/output bus for connecting the control unit 901 to the arrangement 100. Further, a user may control the control unit 901 via the input/output bus. The user may, for example, control quantum computation operations performed by the arrangement 100 via the control unit 901 and the input/output bus.

When the control unit 901 is configured to implement some functionality, some component and/or components of the control unit 901, such as the at least one processor 1001 and/or the memory 1002, may be configured to implement this functionality. Furthermore, when the at least one processor 1001 is configured to implement some functionality, this functionality may be implemented using program code stored, for example, in the memory.

The control unit 901 may be implemented using, for example, a computer, some other computing device, or similar.

FIG. 12 illustrates a flow chart representation of a method 1100 for qubit readout, according to an embodiment.

According to an embodiment, the method 1100 comprises providing the control signal to the controllable energy relaxation structure of the arrangement (block 1101).

The method 1100 may further comprise detecting the readout signal provided by the charge sensing structure of the arrangement (block 1102).

The method 1100 may be performed by, for example, the control unit 901 of FIG. 11.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An apparatus for qubit readout comprising:
at least one qubit;
a controllable energy relaxation structure comprising at least one junction, wherein the controllable energy relaxation structure is coupled to the at least one qubit, and is configured to absorb, in response to a control signal, at least one photon from the at least one qubit via photon-assisted tunnelling of a charge through the at least one junction;
a charge storage configured to store the tunnelled charge; and
a charge sensing structure coupled to the charge storage and configured to provide a readout signal in response to detecting the tunnelled charge in the charge storage.

2. The apparatus according to claim 1, wherein the at least one junction of the controllable energy relaxation structure includes at least one normal metal-insulator-superconductor (NIS) junction, at least one superconductor-insulator-superconductor (SIS) junction, or at least one superconductor-insulator-quantum dot (SIQD) junction.

3. The apparatus according to claim 1, wherein the charge sensing structure includes a Coulomb blockade controlling the readout signal, and wherein the Coulomb blockade of the charge sensing structure is modified by the charge stored in the charge storage coupled to the charge sensing structure.

4. The apparatus according to claim 3, wherein the charge sensing structure includes a single electron transistor (SET), a single Cooper pair transistor (SCPT), a radio-frequency single electron transistor (RF-SET), an inductive single electron transistor (L-SET), or a charge sensing structure based on semiconductor quantum dots, carbon nanotubes, quantum point contacts, or two-dimensional materials.

5. The apparatus according to claim 1, wherein the at least one junction of the controllable energy relaxation structure includes a superconductor-insulator-normal metal-insulator-superconductor (SINIS) junction, wherein the at least one qubit is electromagnetically coupled to the normal metal of the SINIS junction of the controllable energy relaxation structure, and wherein the control signal corresponds to a voltage bias over the SINIS junction.

6. The apparatus according to claim 1, wherein the charge storage is formed by at least (i) a capacitive coupling between the at least one qubit and the controllable energy relaxation structure, and (ii) a capacitance of the at least one junction of the controllable energy relaxation structure.

7. The apparatus according to claim 1, further comprising a charge leakage channel coupled to the charge storage and configured to cause the tunnelled charge to decay in the charge storage.

8. The apparatus according to claim 1, wherein at least one operating parameter of the at least one junction is configured in such a way that, when the control signal is applied, a photon-assisted tunnelling rate is greater than an elastic tunnelling rate in the at least one junction.

9. The apparatus according to claim 8, wherein the at least one operating parameter includes at least an operating temperature below 80 millikelvin and a Dynes parameter below 10⁻⁴.

10. The apparatus according to claim 1, wherein the at least one qubit includes at least one superconductive qubit.

11. A quantum computing system comprising the apparatus according to claim 1 and a control unit communicatively coupled to the apparatus, wherein the control unit is configured to:
provide the control signal to the controllable energy relaxation structure of the apparatus; and
detect the readout signal provided by the charge sensing structure of the apparatus.

12. The quantum computing system according to claim 11, wherein the control signal comprises at least one unipolar or bipolar voltage pulse.

13. The quantum computing system according to claim 12, wherein the at least one bipolar voltage pulse is temporally asymmetric.

14. The quantum computing system according to claim 12, wherein an amplitude of the at least one unipolar voltage pulse corresponds an energy that is less than a superconducting gap energy of the at least one junction of the controllable energy relaxation structure and greater than a difference of the superconducting gap energy of the at least one junction of the controllable energy relaxation structure and a qubit energy of the at least one qubit.

15. The quantum computing system according to claim 12, wherein an amplitude of a first polarity part of the bipolar voltage pulse corresponds an energy that is less than a superconducting gap energy of the at least one junction of the controllable energy relaxation structure and greater than a difference of the superconducting gap energy of the at least one junction of the controllable energy relaxation structure and a qubit energy of the at least one qubit.

16. A method for qubit readout in the apparatus according to claim 1, the method comprising:
providing the control signal to the controllable energy relaxation structure of the apparatus; and
detecting the readout signal provided by the charge sensing structure of the apparatus.

17. A computer program product comprising non-transitory program code configured to perform the method according to claim 16 when the computer program product is executed on a computer.
